(19) United States
(12) Patent Application Publication
(10) Pub. No.: US 2016/0122875 A1
(43) Pub. Date: May 5, 2016

(54) CHEMICAL VAPOR DEPOSITION REACTOR WITH FILAMENT HOLDING ASSEMBLY

(71) Applicant: REC Silicon Inc, Moses Lake, WA (US)

(72) Inventors: Casey M. Kelly, Butte, MT (US); Bryan Joseph Loushin, Butte, MT (US)

(73) Assignee: REC SILICON INC

(21) Appl. No.: 14/534,002

(22) Filed: Nov. 5, 2014

(51) Int. Cl. C23C 16/46; C23C 16/455; C23C 16/24

(52) U.S. Cl. CPC C23C 16/46; C23C 16/24; C23C 16/455

(57) ABSTRACT

Polysilicon crystalline rods are formed by chemical vapor deposition in the reaction chamber of a Siemens reactor. Filament holding assemblies secure vertically extending filaments to electrodes located along the floor of the reactor. A filament holding assembly includes a chuck support member that is mounted on an electrode and that has an upwardly tapering side surface. A chuck is seated on the chuck support member with at least a portion of the chuck support member received within a cavity defined in the base of the chuck with the side surface of the chuck support member engaging the surface that defines the cavity. The cavity can sized and shaped such that a gap is defined between the distal end of the chuck support member and an end wall surface of the cavity. The chuck has an upwardly opening receptacle that receives and holds the end portion of an upwardly extending filament.

### FIELD

The present disclosure relates to methods and apparatus suitable for use in chemical vapor deposition reaction processes for the production of polycrystalline silicon rods.

### BACKGROUND

High purity silicon for use in the semiconductor industry commonly is produced by a process known as chemical vapor deposition (“CVD”). Gas having silicon content is heated to a high temperature within a reaction chamber causing it to decompose and deposit elemental silicon.

One of the widely practiced methods of polysilicon production is referred to as the Siemens method. In this method, a silicon-containing gas, such as monosilane or trichlorosilane, is decomposed and polysilicon is deposited onto electrically heated, high-purity, thin silicon rods located within the chamber of a CVD reactor. The thin silicon rods sometimes are referred to as filaments, seed rods or starter rods. Silicon deposits on the filaments, thereby growing rods of larger diameter. The rods are maintained at elevated temperatures, typically of 700° C. to 1,100° C. to cause gas decomposition and silicon deposition at the surfaces of the rods.

In the Siemens process, the filaments and the resulting growing polysilicon rods typically are heated resistively by passing electrical current along the filaments or rods to provide the thermal energy necessary to decompose the silicon-containing gas. The filaments are attached to electrodes that provide electricity through the base plate of the reactor. The electrodes typically are comprised of copper and have externally threaded top portions that are located inside the reaction chamber. The electrodes typically are connected to the silicon filaments by intermediate carbon pieces known as chucks.

In some Siemens reactors, the chucks have internally threaded sockets that mate with the threads of the electrodes. The chucks are installed in a reactor by threading them onto the electrodes, which is a tedious and time consuming process. The filaments are then seated in other sockets defined by the chucks. This process presents problems for operators that install the chucks and sometimes results in ergonomic injuries. It is a problem that the present chuck arrangement can slow the harvesting of grown silicon rods. In the most common style of reactor, when a rod is harvested, a harvesting arm pulls the rod directly upwardly which places stress on an electrode before the silicon rod and/or the chuck break free from connection with the electrode. There is potential to damage the electrode or cause the rod to break at an undesirable location which can negatively affect reactor yield. There is thus a need for methods and apparatuses to effectively grow and harvest silicon rods without damaging connected electrodes or risking injury to operators. In addition, there is a need for methods and apparatuses for growing silicon rods that allow for faster harvesting and/or increased yields.

### SUMMARY

Disclosed herein are silicon reactors, assemblies and methods involving the use of a chuck support member as an intermediate piece between an electrode and a chuck in a Siemens reactor. This intermediate piece can be formed from copper or a copper alloy (such as a copper-chrome alloy). The intermediate piece can have a threaded bore that mates with the threaded portion of an electrode. The piece can have a profile (height) low enough to prevent the piece from overheating, which can impact yield and quality. The outer-side surface of the piece can be tapered and sized such that the piece can be received by and firmly seated in a matching cavity of a chuck. Surfaces of the piece and chuck can be formed by machining. The chuck support member can protect the integrity of the electrode threads.

Having such a chuck support member avoids damage to the electrode threads that otherwise can occur when a threaded carbon chuck is removed from a threaded electrode. Inclusion of this intermediate piece can enable operators to speed loading and unloading of a reactor, improve the mechanical integrity of the electrodes, reduce stress on the rods and electrodes, and potentially increase the average length of harvested rods.

The foregoing and other features and advantages of the invention will become more apparent from the following detailed description, which proceeds with reference to the accompanying figures.

### BRIEF DESCRIPTION OF THE DRAWINGS

In the drawings:

FIG. 1 is a vertical sectional schematic view of a Siemens reactor containing filament holding assemblies, each including a chuck and a chuck support member, for use in Siemens reactor.

FIG. 2 is a front elevational view of a filament holding assembly, including a chuck and a chuck support member, for use in Siemens reactor.

FIG. 3 is a cross-sectional view taken along line 3-3 of FIG. 1, additionally showing an electrode and a portion of a filament.

FIG. 4 is a front elevational view of the chuck support member of FIG. 1.

FIG. 5 is a bottom plan view of the chuck support member of FIG. 1.

### DETAILED DESCRIPTION

As used herein, the singular terms “a,” “an,” and “the” include plural referents unless context clearly indicates otherwise. Also, as used herein, the term “comprises” means “includes.

Unless otherwise indicated, all numbers expressing quantities or dimensions of components, percentages, temperatures, times, and so forth, as used in the specification or claims are to be understood as being modified by the term “about.” Accordingly, unless otherwise indicated, implicitly or explicitly, the numerical parameters set forth are approximations that may depend on the desired properties sought, limits of detection under standard test conditions/methods, or both. When directly and explicitly distinguishing embodiments from discussed prior art, the embodiment numbers are not approximates unless the word “about” is recited.

CVD reactors for use in the Siemens process typically have a bell jar configuration including a base plate or floor member upon which is fixedly mounted a shell or dome member that defines a gas-tight reaction chamber. Examples of Siemens reactors are described in numerous publications, such as U.S. Pat. No. 4,805,556 A, U.S. Pat. No. 5,545,387 A, U.S. Pat. No. 6,221,155 B1. U.S. Pat. No. 6,544,333 B2, and U.S. Pat. No. 6,749,824 B2. In a Siemens reactor, filaments are attached to electrodes that extend through the base plate and convey electrical current through the base plate to the filaments. The electrodes typically are copper and have externally threaded top portions that are located inside the reaction chamber. The electrodes are physically and electrically connected to the silicon filaments by carbon pieces referred to as “chucks.”

A silicon-bearing gas source (not shown) is in communication with the chamber. Silicon-bearing gas is fed into the chamber, as needed, from the gas source. And spent gas is withdrawn from the chamber as needed. The electrical current heats the filaments sufficiently to cause the silicon-bearing gas, present in the chamber, to decompose and deposit silicon on the filaments.

Described herein are Siemens reactors, filament holding assemblies, and other components for use in such reactors. In the systems described herein, a chuck has a receptacle that receives and holds the end of a filament. A chuck support member is located between the chuck and a corresponding electrode. The chuck can be removed along with the filament during harvesting of a grown rod that comprises silicon deposited on the filament. With a filament holding assembly described herein, when the rod is pulled away from the electrode, the chuck can slidably separate from the chuck support member, which is retained on the electrode. The chuck support member can then be re-used with additional chucks and filaments. In some instances, a chuck will remain seated on a chuck support member when a rod is harvested; but more often, the chuck is removed with the rod.

Filaments, chucks and electrodes are subject to less stress, as compared to conventional Siemens systems, when the filament holding assemblies described herein are used. In some instances, the assemblies and reactors described herein allow for expedited loading and/or unloading of the filaments. In some instances, the assemblies and reactors described herein result in increased yield.

In some instances, the temperature of a chuck and/or the distribution of temperature within a chuck is altered by the presence of a chuck support member during the deposition of silicon, as compared to operation with the chuck being placed directly on the electrode. For example, in some embodiments, the temperatures within receptacle or within the chuck in the vicinity of the filament-holding receptacle are lowered to a more optimal temperature, resulting in less decomposition of deposited polysilicon and improved yields. Such temperature regulation can be accomplished by circulating a cooling fluid, such as deionized water, through one or more passageways that extend through each electrode and/or passageways that extend through the floor of the reactor adjacent to the electrodes.

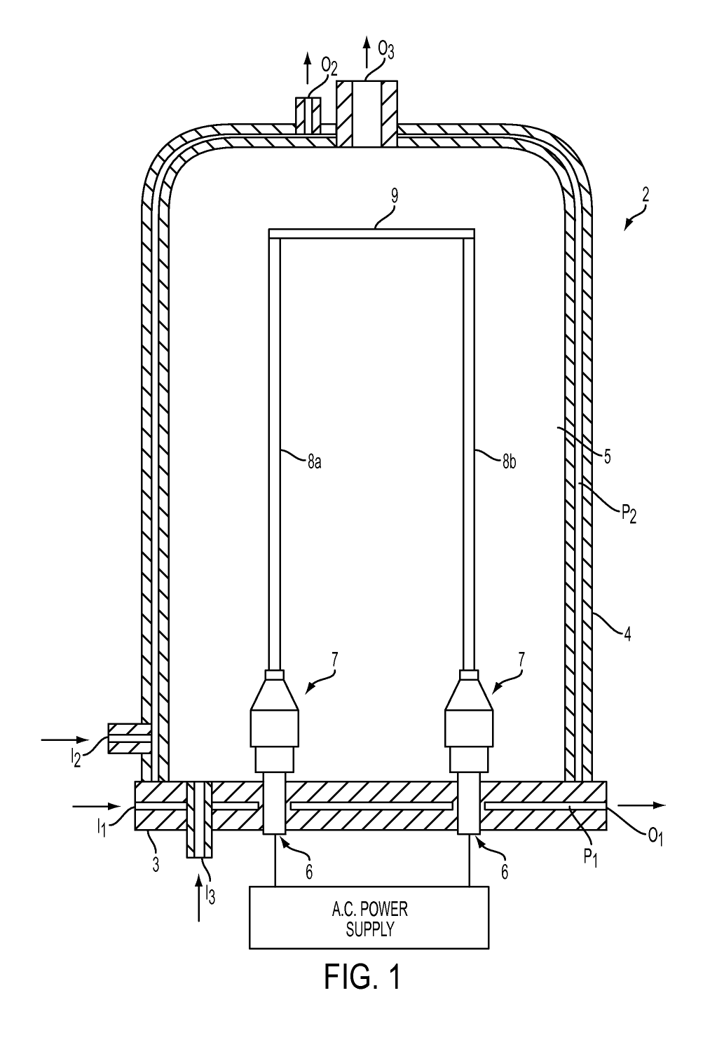

FIG. 1 shows a chemical vapor deposition reactor 2 having walls that include a base plate 3 and a bell jar member 4. The base plate 3 mates with the bell jar member 4 and together provide a vessel having a gas-tight wall that defines a reaction chamber 5. The base plate 3 and bell jar member 4 are double-walled structures having passageways P₁, P₂ through which a cooling fluid can be circulated to cool inwardly facing surfaces of the walls. In the illustrated base plate 3, cooling fluid flows from an inlet I₁ to an outlet O₁. In the illustrated bell jar member 4, cooling fluid flows from an inlet I₂ to an outlet O₂.

One or more electrodes 6 can face into the chamber from the wall, advantageously through the base plate 3. In FIG. 1, two electrodes 6 extend through the base plate 3 with an externally threaded portion 6a of each electrode 6 extending into the chamber 5. The electrodes 6 are electrically connected to an external power source to apply electrical current to the filaments 8a, 8b via filament holding assemblies 7 to heat the filaments. The power source can be a conventional AC source of power of the type normally used for Siemens CVD reactors. The coolant passageway P₁ is configured to route cooling fluid to flow sufficiently near to the electrodes 6 to cool the electrodes. The electrodes 6 also can be cooled by cooling pipes (not shown) that extend into the chamber 5 and define passageways that supply cooling fluid to the vicinity of the electrodes. The cooling pipes may be in physical contract with the electrodes. Embodiments of cooling pipes, including concentrically arranged pipes, are described in U.S. Pat. No. 6,544,333 B2, which is incorporated herein by reference. The cooling fluid typically is water. But another cooling fluid or a heating medium could be circulated through one or more of the passageways in some embodiments.

A filament holding assembly 7 is supported on each electrode 6. Filaments 8a, 8b extend vertically from each filament holding assembly 7. The upper ends of the filaments 8a, 8b are joined by a horizontal filament or bridge 9 to complete an electrical circuit between the two electrodes 6. The illustrated arrangement of two vertical filaments and a bridge is frequently used and sometimes referred to herein as a “hairpin.” Multiple pairs of electrodes and hairpins supported thereon can be contained in a reaction chamber. In the illustrated system, one or more hairpin assemblies can be supported on electrodes extending through the base plate 3.

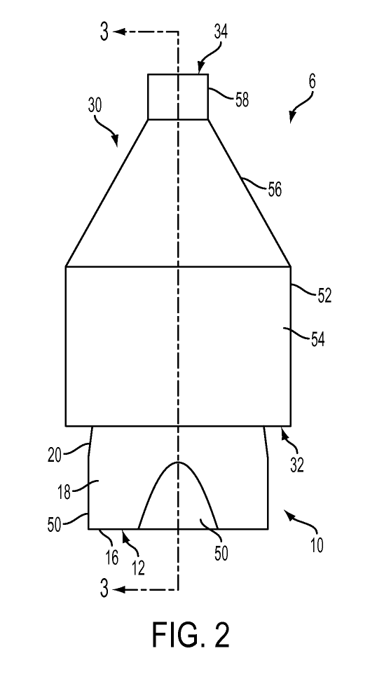

As best seen in FIGS. 2-5, each filament holding assembly 7 can comprise an electrically conductive chuck support member 10 and an electrically conductive chuck 30 having a receptacle for holding a filament 8. The filament holding assembly 7 thus is a portion of an electrical circuit that extends between the electrodes and that includes the holding assemblies 7 and filaments 8, 9.

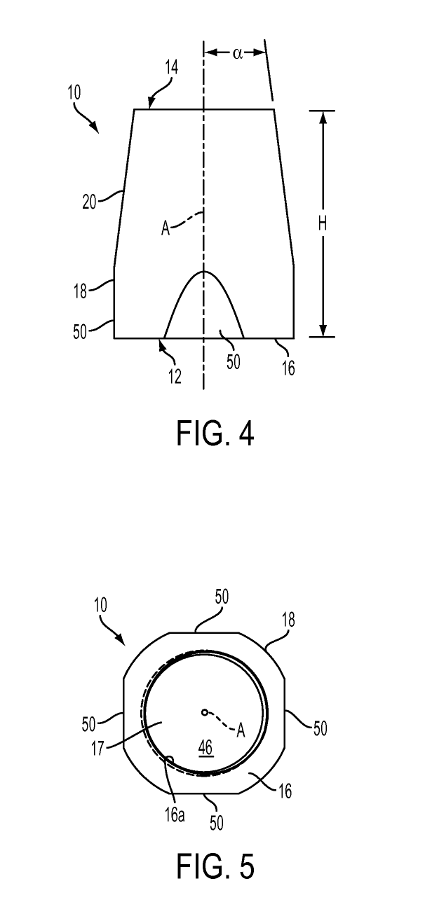

As shown in FIG. 4, the chuck support member 10 can have a proximal end 12 with a proximal end surface 16 configured to engage an electrode and a distal end 14 configured to be inserted into a chuck 30. The proximal end surface 16 can define a socket 17 having an internally threaded cylindrical wall surface 16a of circular cross section. The threaded wall surface 16a is sized and shaped to receive and engage the externally threaded portion 6a of the electrode 6. The chuck support member 10 can be secured on the electrode 6 by aligning the externally threaded portion 6a of the electrode with the internally threaded cylindrical wall 16a of the chuck support member 10 and rotating the chuck support member relative to the electrode. Advantageously, the socket 17 will be sufficiently deep as to accommodate the entire exposed portion of the electrode 6, and at least will accommodate substantially the entire threaded portion 6a of the electrode, so the chuck support member 10 can be maintained at a relatively low temperature by maximum surface area contact with the cooled electrode. Extending between the proximal end 12 and the distal end 14 is an outwardly facing intermediate surface 18. This intermediate surface 18 can comprise a tapered portion 20 that tapers axially away from the proximal end 12 and toward the distal end 14.

The chuck support member 10 best will have a low profile to assist in preventing the chuck support member from exceeding the temperature at which reactant gas decomposes and deposits silicon on the filament holding assembly 7 and to avoid heat-induced off-gassing from the filament holding assembly 7. In particular, the chuck support member 10 advantageously will have a height H of from 1.2 to 2.5 inches as measured between the proximal end 12 and the distal end 14 of the chuck support member, although other heights also are possible. If the chuck support member 10 extends to an elevation that is too far above the upper end of the cooled electrode 6, the chuck 30 may be heated to such a temperature that an undesirably large amount of silicon deposits on the filament holding assembly 7.

The components of the filament holding assembly 7, which includes the chuck 30 and the chuck support member 10, have the requisite toughness, machinability, conductivity, and other characteristics to allow for use in a Siemens reactor. The chuck support member 10 advantageously comprises a substantially non-carbon, electrically conductive material. In some embodiments, the chuck support member 10 comprises copper or a copper chrome alloy (such as a C182 or C101 copper chrome alloy). In some embodiments, the chuck support member 10 consists essentially of copper or copper chrome alloy.

Advantageously the entire volume of the chuck support member 10 will be composed of an electively conductive material, such as entirely composed of copper or a copper chrome alloy. However, in some embodiments, the chuck support member 10 and/or chuck 30 can have one or more electrically insulating portions. These electrically insulating portions may be substantially non-conductive and/or less conductive relative to other portions of the chuck 30 or chuck support member 10. But the electrode 6 and the filament 8 supported thereon must be in electrical communication.

The intermediate surface 18 of the chuck support member 10 can have a noncircular surface portion that is configured to frictionally engage a tool for rotating the chuck support member 10 around the axis of the cylindrical wall of the socket. Advantageously, the chuck support member 10 can have at least one tool-engaging surface portion that is positioned to frictionally engage a jaw of a wrench or of a pair of pliers. The illustrated embodiment has four tool-engaging surface portions 50 that are generally planar, that extend parallel to the axis of the socket 17, and that are spaced apart around the intermediate surface 18 as shown in FIG. 5. The four planar surface portions 50 can be equidistant from the central axis as measured normal to the planar surface portions 50. In the illustrated embodiment, there are two pairs of directly opposing surface portions 50, the surfaces of each pair extending parallel to one other and being located on opposite sides of the axis of the cylindrical wall 16a. As shown, parallel planar surfaces of one pair can coincide with planes perpendicular to the planes corresponding to the other pair of parallel planar surfaces. In other words, the planar surfaces of one pair extend generally perpendicularly to the planar surfaces the other pair. In other embodiments, there can be more or fewer planar surface portions, such as two, three, five, or six or planar surface portions. Although the term “planar” is used herein to refer to the illustrated embodiment, the tool-engaging portions of a chuck support member surface need not be perfectly planer or flat, but need only provide a surface region having a noncircular cross-section where a tool can engage the chuck support member 10 and apply force to urge the chuck support member to rotate about the axis A₁ relative to an electrode 6 on which the chuck support member is mounted.

As an alternative to providing tool-engaging flattened surface portions as shown in the drawings, the chuck support member 10 could have at least one radially projecting tab or lug (not shown) that extends outwardly from the surface 18 of the chuck support member with the tab being sized and shaped to engage a tool suitable to apply force to rotate the chuck support member about the axis A₁ relative to the electrode 6.

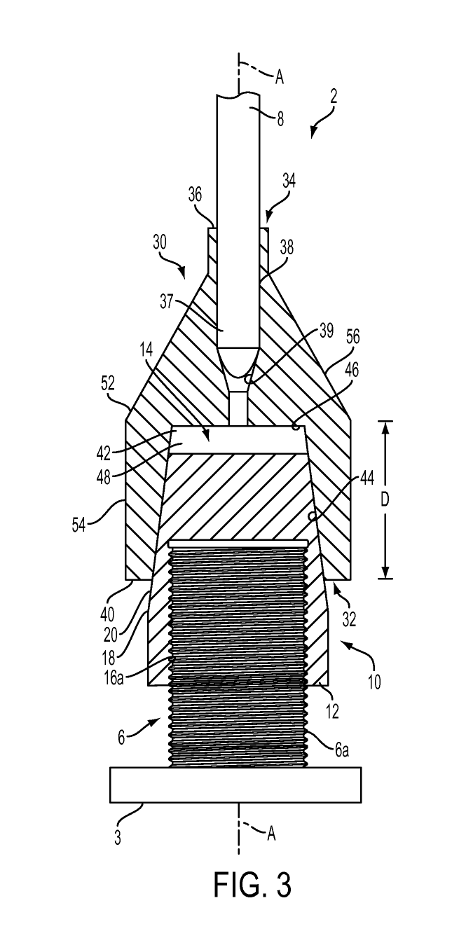

Referring to FIGS. 2-3, the illustrated chuck 30 has a proximal end 32 configured to receive and be supported by the chuck support member 10 and has a distal end 34 that is configured to hold the filament. The distal end 34 can comprise a distal end surface 36 that defines a receptacle 38 configured to receive an end portion 37 of the filament 8. The distal end surface 36 includes a filament-engaging surface portion 39 positioned to support the filament 8 in the receptacle 38. The proximal end 32 can comprise a proximal end surface 40 that defines a cavity 42. In particular, the proximal end surface 40 can have a flared side wall surface 44 that faces inwardly, flares toward the proximal end 32, and generally conforms to the tapered portion 20 of the intermediate surface of the chuck support member and have an end wall surface 46 located at the base of the cavity 42. The illustrated end wall surface 46 extends perpendicular to the axis, but that is not required in all embodiments. The distal end 14 of the chuck support member can be received within the cavity 42 with at least a portion of the tapered surface 20 wedgingly engaging at least a portion of the flared side wall surface 44.

Advantageously, the cavity 42 will be of sufficient depth D and the angle of the flared side wall surface 44 and angle of the tapered surface 20 will be such that a gap 48 is defined between the distal end 34 of the chuck support member 10 and the end wall surface 46 of the chuck 30. To avoid wobbling of the filament 8, it is better for the flared side wall surface 44 to engage the tapered surface 20 than for the distal end 14 of the chuck support member 10 to engage the end wall surface 46 of the chuck 30. This illustrated arrangement, in which axially extending surfaces wedgingly engage, also avoids the need to precisely machine the components so that the exterior of the chuck support member 10 exactly conforms to the surface that defines the cavity 42 of the chuck 30 to prevent wobbling of the filament. The presence of the gap 48 is further advantageous because it provides expansion leeway for a filament holding assembly 7 wherein the chuck support member 10 and the chuck 30 respectively are made of different materials that do not have exactly the same coefficient of thermal expansion.

The illustrated chuck 30 has an outwardly facing intermediate surface 52 that extends between the distal end surface 36 and the proximal end surface 40 of the chuck, with at least a portion 54 of the intermediate surface 52 being non-tapered. The illustrated intermediate surface 52 also has a tapered portion 56, which can be located in the vicinity of the receptacle 38 and which tapers toward the distal end 34. This tapered portion 56 advantageously is distal to the non-tapered portion 54 in an installed filament holding assembly 7. The distal end 34 can also comprise a non-tapered surface 58, distal to the tapered portion 56 of the intermediate surface 52.

Advantageously both the exterior perimeter of the chuck support member 10 and the interior perimeter of the chuck 30 will be of the same cross-sectional shape at the location where the tapered portion 20 engages the flared side wall surface 44. With this arrangement, when the chuck support member is inserted into the chuck, a tight seal is formed between surfaces of the chuck support member 10 and the chuck 30 around the entire perimeters of tapered portion 20 and the flared side wall surface 44 at the region where the tapered portion and the flared side wall surface meet. The seal blocks reactant gas from flowing into the cavity 42.

To facilitate the formation of a good seal and for convenience of inserting the chuck support member 10 into the chuck 30, both the tapered portion 20 and the flared side wall surface 44 can be circular in axial cross-section. For example, in the illustrated embodiment, each of the tapered surface portion 20 and the flared surface portion 44 is a frustum of a right circular cone. In this embodiment, the filament holding assembly 7 has an axis A₁, each of the tapered portion 20 and the side wall surface 44 is symmetrical about an axis, and the axes of both the tapered portion 20 and the side wall surface 44 coincide with the axis A₁. When the assembly 7 is installed in a reactor 2, the axis A₁ extends generally vertically. In the illustrated embodiment, the axis of the tapered surface 20 and the axis of the side wall surface 44 also coincide with the axis of the cylindrical threaded wall surface 16a of the socket 17. Advantageously, the chuck support member and chuck, with the exception of tool engaging surfaces, will be symmetrical with the axis of symmetry begin the axis A₁ of the filament holding assembly 7.

The tapered portion 20 of the intermediate surface 18 of the chuck support member 10 and the side wall surface 44 of proximal end surface 40 of the chuck 30 can have various degrees of slope. Referring to FIG. 4, the tapered portion 20 can be tapered at an angle α of from 10 to 22 degrees relative to the axis. In some embodiments, this angle of taper is from 12 degrees to 16 degrees, particularly 14 degrees. If the angle α is too large, the chuck support member 10 and chuck 30 will be of an undesirably large diameter. If the angle is too small, the chuck 30 will extend to an undesirably large distance from the cooled electrode, such that overheating of the chuck can become a problem.

The side wall surface 44 best is flared at about the same angle as the angle of taper of the tapered portion 20. In some embodiments, the angle of taper of the tapered portion 20, while similar to the slope of the flared side wall surface 44, is slightly different such that the distal end 14 of the chuck support member 10 incompletely inserts into the cavity 42, leaving a small amount of space around a portion of the outside of the tapered portion 20 between the tapered portion 20 and the flared side wall surface 44. When the angles of tapered surface 20 and the flared surface 44 are not identical, friction between the tapered surface and the flared surface is reduced, which can make it easier to separate the chuck support member 10 from the chuck 30 during harvesting of a grown rod.

In various embodiments, a plurality of generally vertically extending filaments can extend from a plurality of chucks within a given reactor. Each filament can have a lower end seated in a receptacle of a separate chuck. Each chuck can be positioned atop a chuck support member as described above. The reactor can comprise one or more bridges, each bridge extending between the upper ends of two of the filaments forming a hairpin.

When the reactor 2 is in use, the filament 8 can be heated by supplying electrical current to the filament 8 via the electrode 6, the chuck support member 10 and the chuck 30. A silicon-bearing precursor gas is supplied to the heated filament such that the gas pyrolitically decomposes and deposits silicon onto the filament 8 to produce a polysilicon rod of increased diameter. In the system of FIG. 1, the precursor gas is delivered into the chamber 5 via a gas inlet I₃. Spent precursor gas exits the chamber 5 via a gas outlet O₃.

The chuck 30 and the polysilicon rod of increased diameter can be removed simultaneously from the chuck support member 10 to harvest the polysilicon rod. In particular, the chuck 30 and polysilicon rod can be removed by pulling upwardly on the rod whereupon the chuck 30 slides axially off the chuck support member 10, without first separating the polysilicon rod from the chuck 30, and without removing the chuck support member 10 from the electrode 6. The chuck support member 10 may be reusable. After harvesting, a new chuck and filament may be placed on the distal end 14 of the chuck support member 10 and used to produce a second polysilicon rod. In certain embodiments, the chuck support member 10 may be used multiple additional times, such as two, three, four, or five times additional times, to produce additional polysilicon rods, such as to produce two, three, four or five additional polysilicon rods.

In the illustrated embodiment, the filaments 8 extend vertically. During harvesting, the chuck slides vertically upwardly. However, in certain types of reactors, the filaments can be mounted horizontally or in some other direction. In such reactors chucks may slide horizontally during harvesting, or in some other direction depending upon the orientation of the filaments in the reactor.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. The invention is all that comes within the scope and spirit of these claims.

1. A filament holding assembly for securing a vertically extending filament to an electrode in a reactor for the production of a polysilicon crystalline rod by chemical vapor deposition, the assembly comprising:
an electrically conductive chuck support member having a proximal end, a distal end, a surface that is located at the proximal end and is configured to engage an electrode in a chemical vapor deposition reactor, and an outwardly facing intermediate surface that extends between the proximal end and the distal end with at least a portion of the intermediate surface tapering away from the proximal end and toward the distal end; and
an electrically conductive chuck having a proximal end, a distal end, a distal end surface that is located at the distal end and that defines a receptacle configured to receive an end portion of a filament, the distal end surface including a filament-engaging surface portion positioned to support a filament in the receptacle, a proximal end surface that is located at the proximal end and that defines a cavity, and a side wall surface that faces inwardly, flares toward the proximal end, and generally conforms to at least a portion of the tapered portion of the intermediate surface of the chuck support member,
wherein the distal end of the chuck support member is received within the cavity with the tapered portion of the intermediate surface engaging the side wall surface and wherein the cavity is of sufficient depth that a space is defined between the distal end of the chuck support member and the chuck.

2. The filament holding assembly of claim 1, wherein:
the tapered portion of the intermediate surface of the chuck support member is a frustum of a right circular cone;
the flared portion of the proximal end surface of the chuck is a frustum of a right circular cone; and
the axis of the tapered portion of the intermediate surface of the chuck support member coincides with the axis of the flared portion of the proximal end surface of the chuck.

3. The filament holding assembly of claim 1, wherein:
the proximal end surface of the chuck support member defines a socket that has an internally threaded cylindrical wall and that is sized and shaped to receive an externally threaded portion of an electrode of a reactor for the production of a polysilicon crystalline rod by chemical vapor deposition; and
the intermediate surface of the chuck support member has a noncircular surface portion that is configured to frictionally engage a tool for rotating the chuck support member around the axis of the cylindrical wall of the socket.

4. The filament holding assembly of claim 3, wherein the noncircular surface portion of the intermediate surface of the chuck support member comprises at least one planar surface portion that extends parallel to the axis of the cylindrical wall of the socket and that is positioned to frictionally engage the tool.

5. The filament holding assembly of claim 3, wherein:
the noncircular surface portion of the intermediate surface of the chuck support member comprises at least four planar surface portions that extend parallel to the axis of the socket and are positioned to frictionally engage the jaws of a wrench,
the four planar surface portions are equidistant from the axis as measured normal to the planar surface portions,
a first two of the planar surface portions extend parallel to each other and are located on opposite sides of the axis of the cylindrical wall of the socket, and
a second two of the planar surface portions extend parallel to each other and are located on opposite sides of the axis of the cylindrical wall of the socket, with the first two of the planar surfaces extending perpendicular to the second two of the planar surfaces.

6. The filament holding assembly of claim 3, wherein the axis of the tapered portion of the intermediate surface of the chuck support member and the axis of the flared portion of the proximal end surface of the chuck coincide with the axis of the cylindrical wall of the socket.

7. The filament holding assembly of claim 1, wherein the chuck support member comprises a substantially non-carbon, electrically conductive material.

8. The filament holding assembly of claim 1, wherein the chuck support member consists essentially of copper or a copper chrome alloy.

9. The filament holding assembly of claim 1, wherein the chuck support member consists essentially of a C182 or C101 copper chrome alloy.

10. The filament holding assembly of claim 1, wherein the height of the chuck support member is from 1.2 inches to 2.5 inches as measured between the proximal end and the distal end of the chuck support member.

11. The filament holding assembly of claim 1, wherein:
the tapered portion of the intermediate surface of the chuck support member is tapered at an angle of from 10 to 22 degrees relative to the axis of the tapered portion of the intermediate surface of the chuck support member; and
the side wall surface of the chuck is flared at about the same angle as the angle of taper of the tapered portion of the intermediate surface of the chuck support member.

12. The filament holding assembly of claim 1, wherein:
the intermediate surface of the chuck support member is tapered at an angle of between about 12 and about 16 degrees; and
the side wall surface of the chuck is flared at the same angle as the angle of taper of the tapered portion of the intermediate surface of the chuck support member.

13. The filament holding assembly of claim 1, wherein the proximal end of the chuck further comprises an outwardly facing intermediate surface that extends between the distal end surface and the proximal end surface of the chuck, with at least a portion of the intermediate surface being non-tapered.

14. A reactor for the production of a polysilicon crystalline rod by chemical vapor deposition, the reactor comprising:
a vessel having a gas-tight wall that defines a reaction chamber;
an electrode located at the wall, with a portion of the electrode facing into the chamber;
an electrically conductive chuck support member located inside the chamber, the chuck support member having a proximal end, a distal end, a surface that is located at the proximal end and that engages the electrode, and an outwardly facing intermediate surface that extends between the proximal end and the distal end with at least a portion of the intermediate surface tapering away from the proximal end and toward the distal end; and
an electrically conductive chuck located inside the chamber, the chuck having a proximal end, a distal end, a distal end surface that is located at the distal end and that defines a receptacle configured to receive an end portion of a filament, the distal end surface including a filament-engaging surface portion positioned to support a filament in the receptacle, a proximal end surface that is located at the proximal end and that defines a cavity, and a side wall surface that faces inwardly, flares toward the proximal end, and generally conforms to at least a portion of the tapered portion of the intermediate surface of the chuck support member,
wherein the distal end of the chuck support member is received within the cavity with the tapered portion of the intermediate surface engaging the side wall surface and wherein the cavity is of sufficient depth that a space is defined between the distal end of the chuck support member and the chuck; and
a filament located inside the chamber, the filament having an end portion received within the receptacle.

15. The reactor of claim 14, further comprising:
a source of electrical power connected to the electrode to apply power to the filament to heat the filament; and
a source of a silicon-bearing gas in communication with the chamber for supplying the gas into the chamber.

16. The reactor of claim 14, wherein the proximal end of the chuck further comprises an outwardly facing intermediate surface that extends between the distal end surface and the proximal end surface of the chuck, with at least a portion of the intermediate surface being non-tapered.

17. The reactor of claim 14, wherein the chuck support member comprises a substantially non-carbon, electrically conductive material.

18. The reactor of claim 14, wherein the inwardly facing flared surface of the chuck and the intermediate surface of the chuck support member are frustoconical with an axis that extends generally vertically.

19. The reactor of claim 14, wherein:
the electrode has an externally threaded cylindrical surface; and
a downwardly opening socket is defined in the proximal end of the chuck support member, the socket being at least partially defined by an internally threaded cylindrical wall surface that engages the externally threaded surface of the electrode.

20. The reactor of claim 14, wherein the chuck support member consists essentially of copper or a copper chrome alloy.

21. The reactor of claim 14, wherein the chuck support member comprises a C182 or C101 copper chrome alloy.

22. The reactor of claim 14, wherein the height of the chuck support member is between about 1.2 inches and about 2.5 inches as measured between the proximal end and the distal end of the chuck support member.

23. The reactor of claim 14, wherein:
the tapered portion of the intermediate surface of the chuck support member is tapered at an angle of between about 10 and about 22 degrees; and
the side wall surface of the chuck is flared at the same angle as the angle of taper of the tapered portion of the intermediate surface of the chuck support member.

24. The reactor of claim 14, wherein:
the tapered portion of the intermediate surface of the chuck support member is tapered at an angle of between about 12 and about 16 degrees; and
the side wall surface of the chuck is flared at the same angle as the angle of taper of the tapered portion of the intermediate surface of the chuck support member

25. A reactor for forming polycrystalline silicon rods, the reactor comprising:
a base plate;
a bell jar that mates with the baseplate to form a gas-tight enclosure that defines a reaction chamber;
a plurality of electrodes facing into the chamber from the baseplate;
a plurality of electrically conductive chuck support members located inside the chamber, each chuck support member having a proximal end, a distal end, a proximal end surface that is located at the proximal end and that engages one of the electrodes, and an outwardly facing intermediate surface that extends between the proximal end and the distal end with at least a portion of the intermediate surface being tapered, tapering away from the proximal end and toward the distal end;
a plurality of electrically conductive chucks located inside the chamber, each chuck having a proximal end, a distal end, a distal end surface that is located at the distal end and that defines a receptacle configured to receive an end portion of a filament, and a proximal end surface that is located at the proximal end and that defines a cavity, a portion of the proximal end surface being a side wall surface that faces inwardly, flares toward the proximal end, and generally conforms to the intermediate surface of the chuck support member, another portion of the proximal end surface being an end wall surface located at the base of the cavity, the distal end of each chuck support member being received within the cavity of one of the chucks with at least a portion of the tapered surface of the chuck support member engaging at least a portion of the flared portion of the proximal end surface of the chuck, the cavity being of sufficient depth that a gap is defined between the distal end of the chuck support member and the end wall surface of the chuck;
a plurality of generally vertically extending filaments located inside the chamber, each filament having a lower end seated in one of the receptacles and an upper end;
one or more bridges, each bridge extending between the upper ends of two of the filaments to form a hairpin;
a power source connected to electrodes to supply electrical power to the electrodes; and
a source of silicon-bearing gas in communication with the chamber.

26. A method for forming a polycrystalline silicon rod within a chamber of chemical vapor deposition reactor, the method comprising:
supporting an electrically conductive chuck support member on an electrode on the floor of a chemical vapor deposition reactor, the chuck support member having a proximal end, a distal end, a proximal end surface that is located at the proximal end and is configured to engage an electrode in a chemical vapor deposition reactor, and an outwardly facing intermediate surface that extends between the proximal end and the distal end with at least a portion of the intermediate surface tapering away from the proximal end and toward the distal end;
supporting an electrically conductive chuck on the chuck support member, the chuck having a proximal end, a distal end, a distal end surface that is located at the distal end and that defines a receptacle configured to receive an end portion of a filament, and a proximal end surface that is located at the proximal end and that defines a cavity, a portion of the proximal end surface being a side wall surface that faces inwardly, flares toward the proximal end, and generally conforms to the intermediate surface of the chuck support member, a second portion of the proximal end surface being an end wall surface located at the base of the cavity, wherein the distal end of the chuck support member is received within the cavity with at least a portion of the tapered surface of the chuck support member engaging at least a portion of the flared portion of the proximal end surface of the chuck, the cavity being of sufficient depth that a gap is defined between the distal end of the chuck support member and the end wall surface of the chuck;
supporting a generally vertically extending filament in the receptacle of the chuck;
heating the filament by supplying electrical current to the filament via the electrode, chuck support member, and chuck;
supplying a silicon precursor gas to the heated filament such that the gas pyrolitically decomposes and deposits silicon onto the filament to produce a polysilicon rod of increased diameter; and
simultaneously removing the chuck and the polysilicon rod of increased diameter from the chuck support member to harvest the polysilicon rod.

27. The method of claim 26, wherein the chuck support member comprises a substantially non-carbon, electrically conductive material.

28. The method of claim 26, wherein the removing comprises sliding the chuck axially off the chuck support member without first removing the polysilicon rod from the chuck and without removing the chuck support member from the electrode.

29. The method of claim 26, further comprising
positioning a second chuck on the chuck support member,
positioning a second filament at a distal end portion of the second chuck;
conducting electrical and heat energy from the chuck support member to the second chuck,
depositing silicon on the second filament to produce a second polysilicon rod; and
simultaneously removing the second chuck and the second polysilicon rod from the chuck support member.
